(19) United States
(12) Patent Application Publication
(10) Pub. No.: US 2025/0370024 A1
(43) Pub. Date: Dec. 4, 2025

(54) POWER NETWORK SYSTEMS AND METHODS FOR DETECTING COMPONENT ERROR

(71) Applicant: Torc Robotics, Inc., Blacksburg, VA (US)

(72) Inventors: Xholjon Dede, Esslingen am Neckar (DE); Gerardas Skeberdis, Hickory Hills, IL (US); Matthew Swanson, Blacksburg, VA (US); Sebastian Dingler, Stuttgart (DE); Simon Hanrath, Tuebingen (DE)

(21) Appl. No.: 18/680,907

(22) Filed: May 31, 2024

(51) Int. Cl. G01R 31/00; G01R 31/08

(52) U.S. Cl. CPC G01R 31/007; G01R 31/086; G01R 31/088

(57) ABSTRACT

The present disclosure generally relates to systems and methods for fault detection and management in power network connections. An autonomy computing system analyzes test signals to identify cable conditions and decides on actions based on a fault database. Additionally, a power management system, equipped with a processor, monitors power networks, evaluates fault severity, and implements remedial actions to ensure system integrity. A method for detecting power network faults involves transmitting test signals, assessing signal degradation, and initiating appropriate responses to maintain the operation of autonomy systems. These innovations enhance the reliability and efficiency of power network management.

### TECHNICAL FIELD

The field of the disclosure relates generally to detecting component operation errors from power network data and, more specifically, monitoring power networks of autonomous trucks to detect a condition utilizing physical characteristics of the component.

### BACKGROUND OF THE INVENTION

Autonomous vehicles, semi-autonomous vehicles, non-autonomous vehicles, and smart vehicles generally include sensors that provide information during operation of the vehicles. For example, an autonomous and semi-autonomous vehicle may use information from the sensors to perform various operations such as controlling or regulating acceleration, braking, or steering. Other non-autonomous or smart vehicles may present information from the sensors to a user to facilitate the user operating the vehicle or diagnosing an operating status of the vehicle.

On at least some autonomous vehicles, for example, the sensors may include radio detection and ranging (RADAR) sensors, light detection and ranging (LiDAR) sensors, cameras, acoustic sensors, temperature sensors, or inertial navigation system (INS). The sensors collect information representing the environment while the vehicle is traveling. However, while the sensors can capture information about the environment surrounding the autonomous vehicle, conventional autonomous vehicles lack the ability to monitor the status of the sensors. The sensors must remain operational for safe operation of the autonomous vehicle.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY OF THE INVENTION

In one aspect, an autonomous vehicle includes a power management system for detecting a fault in a power network is provided. The power management system also includes a signal generator configured to transmit a test signal through the power network to a component. The system also includes a receiver coupled to the power network and configured to receive a test signal response corresponding to the test signal. The system also includes a memory storing a fault database. The system also includes a processor coupled to the receiver and the memory, the processor configured to process the test signal response to detect a condition in the power network, compare the condition to a fault database, and initiate shutdown of the component or conditional operation of the component based on a severity assessment from the fault database.

In another aspect, a power management system is provided. The power management system also includes an electric load of an autonomy computing system. The system also includes a power network electrically connected to the electric load, where the power network is monitored by a processor. The system includes a processor configured to identify a condition on the power network from a test signal transmitted through the power network, identify a fault corresponding to the condition in a fault database, compute a severity assessment for the fault, and initiate a remediation response may include shutdown of the electric load or reduced operation of the power network.

In yet another aspect, a method for detecting power network faults is provided. The method also includes transmitting a test signal into a power network connection. The method also includes transmitting a test signal into a power network. The method also includes computing degradation of the test signal. The method also includes detecting a condition on the power network based on the degradation, the detection may include comparing the degradation to a fault database and performing a severity assessment of the condition on continued operation of an autonomous vehicle. The method also includes initiating a remediation response on a component connected to the power network to maintain operation of the autonomous vehicle.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a schematic diagram of an autonomous vehicle;

FIG. 2 is a block diagram of an autonomous vehicle;

FIG. 3 is a block diagram of an embodiment of the power network monitoring system;

FIG. 4 is a flow chart of an embodiment of a method of operation of the power network system shown in FIG. 3;

FIG. 5 is a flow chart of an embodiment of a method of detecting sensor errors form a power network; and

FIG. 6 is a block diagram of an example computing device.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure. The following terms are used in the present disclosure as defined below.

An autonomous vehicle: An autonomous vehicle is a vehicle that is able to operate itself to perform various operations such as controlling or regulating acceleration, braking, steering wheel positioning, without any human intervention. An autonomous vehicle has an autonomy level of level-4 or level-5 recognized by National Highway Traffic Safety Administration (NHTSA).

A semi-autonomous vehicle: A semi-autonomous vehicle is a vehicle that is able to perform a number of driving related operations such as keeping the vehicle in lane and/or parking the vehicle without human intervention. A semi-autonomous vehicle has an autonomy level of level-1, level-2, or level-3 recognized by NHTSA.

A non-autonomous vehicle: A non-autonomous vehicle is a vehicle that is neither an autonomous vehicle nor a semi-autonomous vehicle. A non-autonomous vehicle has an autonomy level of level-0 recognized by NHTSA.

The disclosed power management system analyzes changes in power network characteristics to detect a condition affecting an autonomy computing system. The power management system generates, transmits, and analyzes a test signal through the power network to detect the condition. The test signal is transmitted from the power management system through the power network to the component. In various embodiments, the component is associated with autonomous operation of the vehicle by the autonomy computing system. In various embodiments, the power management system monitors for a condition by transmitting and analyzing test signals prior to detection of the condition impacting the autonomous operation of the vehicle. The power management system monitors the test signals to detect the condition. The power management system receives a test signal response and collects test signal data. The test signal data includes the degradation of the test signal resulting from the transmission of the test signal and the test signal response to detect the condition.

The power management system processes the test signal data to perform a severity assessment for the condition. The power management system processes the test signal data to quantify the effect of the condition on the operation of the autonomy computing system for the severity assessment. In some embodiments, the test signal data from the condition is correlated to a fault database, the fault database includes a plurality of known faults and the corresponding responses to the faults. When the test signal data does not correlate to a known fault in the fault database, the system may perform additional diagnostics for the condition to perform a severity assessment. In various embodiments, the system generates an alert corresponding to the unknown fault. For example, the alert can be transmitted to the autonomy computing system to indicate manual review of the fault or to modify the operation of power management system.

When a condition impacts a component, it generally negatively impacts the operation of the autonomous vehicle. For example, the condition may be a communication failure, a software bug, a hardware failure, a power supply fluctuation, etc. Conventionally, detecting the conditions is performed on the component level. To ensure the autonomous vehicle can continuously function, conventionally, sensor data, for example, is continuously monitored for errors, which can then be correlated to a failure of the sensor component. This method, while prevalent, necessitates the actual occurrence of a condition with enough significance to affect the sensor data, which is a disadvantage given the autonomous vehicle relies on the sensor data for safe operation. Accordingly, improved sensor error detection is desired.

The power management system determines whether the condition is a critical fault or a minor fault from the severity assessment. A minor fault includes a condition that allows for continued operation of the autonomous vehicle. For example, the autonomy computing system reconfigures the component associated with the condition for reduced functionality or conditional functionality for a minor fault. A critical fault impacts the ability of the autonomy computing system to operate the autonomous vehicle. For example, the autonomy computing system initiates a shutdown or a minimum risk maneuver for critical faults. The power management system initiates a response by the autonomy computing system upon the result of the severity assessment for the detected condition.

Detecting component conditions from the characteristics of the power network improves the safety and reliability of autonomous vehicles. Evaluating and monitoring physical characteristics of the power network leverages the power network infrastructure of the autonomous vehicle for early detection of a condition. Detecting the condition on the power network enables the autonomy computing system to initiate a response to the condition before the condition affects the operation of the component. For example, the autonomy computing system will shut down the component or conditionally operate the component based on the severity of the condition.

Autonomous vehicles utilize a broad range of sensors and other electrical components to facilitate operation of the autonomous vehicle. The electrical components include sensors, computing systems, and other hardware devices used to facilitate autonomous operation. The autonomy computing system relies on continuous operation of the components to safely operate the autonomous vehicle. The autonomous truck includes, for example, a power network distributing power to the various components. In various embodiments, the power network includes a plurality of conductors for carrying power signals, data signals, or a combination of both. Physical characteristics of a power network can indicate conditions affecting the components connected to the power network. In particular, changes to the characteristics of the power network are detectable prior to impacting the operation of the component. Accordingly, the system provides improved component monitoring by detecting conditions on the power network.

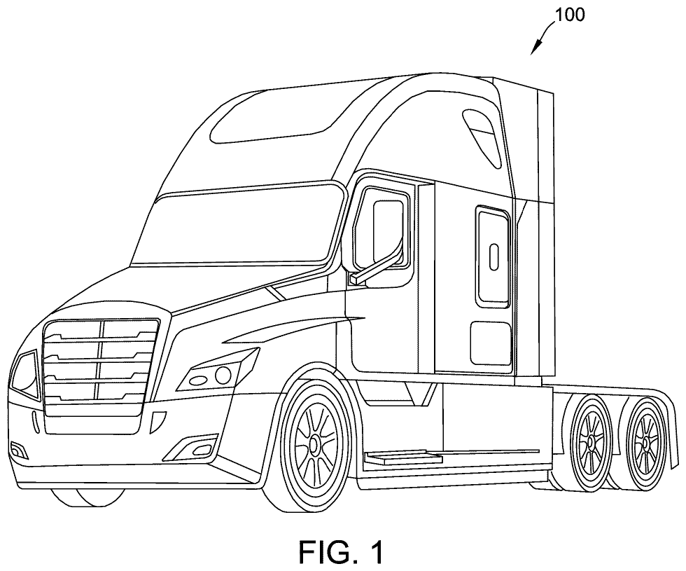

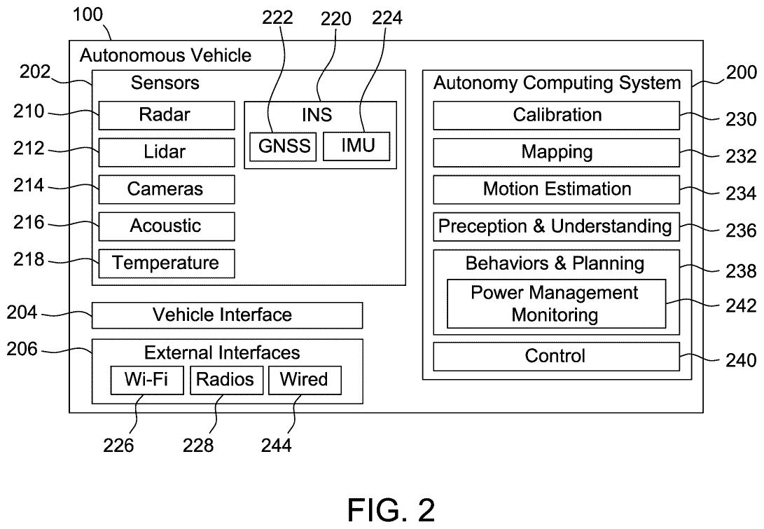

FIG. 1 is a schematic diagram of an autonomous vehicle 100. FIG. 2 is a block diagram of autonomous vehicle 100 shown in FIG. 1. In the example embodiment, autonomous vehicle 100 includes autonomy computing system 200, sensors 202, a vehicle interface 204, and external interfaces 206.

In the example embodiment, sensors 202 may include various sensors such as, for example, radio detection and ranging (RADAR) sensors 210, light detection and ranging (LiDAR) sensors 212, cameras 214, acoustic sensors 216, temperature sensors 218, or inertial navigation system (INS) 220, which may include one or more global navigation satellite system (GNSS) receivers 222 and one or more inertial measurement units (IMU) 224. Other sensors 202 not shown in FIG. 2 may include, for example, acoustic (e.g., ultrasound), internal vehicle sensors, meteorological sensors, or other types of sensors. Sensors 202 generate respective output signals based on detected physical conditions of autonomous vehicle 100 and its proximity. As described in further detail below, these signals may be used by autonomy computing system 120 to determine how to control operation of autonomous vehicle 100.

Cameras 214 are configured to capture images of the environment surrounding autonomous vehicle 100 in any aspect or field of view (FOV). The FOV can have any angle or aspect such that images of the areas ahead of, to the side, behind, above, or below autonomous vehicle 100 may be captured. In some embodiments, the FOV may be limited to particular areas around autonomous vehicle 100 (e.g., forward of autonomous vehicle 100, to the sides of autonomous vehicle 100, etc.) or may surround 360 degrees of autonomous vehicle 100. In some embodiments, autonomous vehicle 100 includes multiple cameras 214, and the images from each of the multiple cameras 214 may be stitched or combined to generate a visual representation of the multiple cameras' FOVs, which may be used to, for example, generate a bird's eye view of the environment surrounding autonomous vehicle 100. In some embodiments, the image data generated by cameras 214 may be sent to autonomy computing system 200 or other aspects of autonomous vehicle 100, and this image data may include autonomous vehicle 100 or a generated representation of autonomous vehicle 100. In some embodiments, one or more systems or components of autonomy computing system 200 may overlay labels to the features depicted in the image data, such as on a raster layer or other semantic layer of a high-definition (HD) map.

LiDAR sensors 212 generally include a laser generator and a detector that send and receive a LiDAR signal such that LiDAR point clouds (or “LiDAR images”) of the areas ahead of, to the side, behind, above, or below autonomous vehicle 100 can be captured and represented in the LiDAR point clouds. Radar sensors 210 may include short-range RADAR (SRR), mid-range RADAR (MRR), long-range RADAR (LRR), or ground-penetrating RADAR (GPR). One or more sensors may emit radio waves, and a processor may process received reflected data (e.g., raw radar sensor data) from the emitted radio waves. In some embodiments, the system inputs from cameras 214, radar sensors 210, or LiDAR sensors 212 may be fused or used in combination to determine conditions (e.g., locations of other objects) around autonomous vehicle 100.

GNSS receiver 222 is positioned on autonomous vehicle 100 and may be configured to determine a location of autonomous vehicle 100, which it may embody as GNSS data, as described herein. GNSS receiver 222 may be configured to receive one or more signals from a global navigation satellite system (e.g., Global Positioning System (GPS) constellation) to localize autonomous vehicle 100 via geolocation. In some embodiments, GNSS receiver 222 may provide an input to or be configured to interact with, update, or otherwise utilize one or more digital maps, such as an HD map (e.g., in a raster layer or other semantic map). In some embodiments, GNSS receiver 222 may provide direct velocity measurement via inspection of the Doppler effect on the signal carrier wave. Multiple GNSS receivers 222 may also provide direct measurements of the orientation of autonomous vehicle 100. For example, with two GNSS receivers 222, two attitude angles (e.g., roll and yaw) may be measured or determined. In some embodiments, autonomous vehicle 100 is configured to receive updates from an external network (e.g., a cellular network). The updates may include one or more of position data (e.g., serving as an alternative or supplement to GNSS data), speed/direction data, orientation or attitude data, traffic data, weather data, or other types of data about autonomous vehicle 100 and its environment.

IMU 224 is a micro-electrical-mechanical (MEMS) device that measures and reports one or more features regarding the motion of autonomous vehicle 100, although other implementations are contemplated, such as mechanical, fiber-optic gyro (FOG), or FOG-on-chip (SiFOG) devices. IMU 224 may measure an acceleration, angular rate, and or an orientation of autonomous vehicle 100 or one or more of its individual components using a combination of accelerometers, gyroscopes, or magnetometers. IMU 224 may detect linear acceleration using one or more accelerometers and rotational rate using one or more gyroscopes and attitude information from one or more magnetometers. In some embodiments, IMU 224 may be communicatively coupled to one or more other systems, for example, GNSS receiver 222 and may provide input to and receive output from GNSS receiver 222 such that autonomy computing system 200 is able to determine the motive characteristics (acceleration, speed/direction, orientation/attitude, etc.) of autonomous vehicle 100.

In the example embodiment, autonomy computing system 200 employs vehicle interface 204 to send commands to the various aspects of autonomous vehicle 100 that control the motion of autonomous vehicle 100 (e.g., engine, throttle, steering wheel, brakes, etc.) and to receive input data from one or more sensors 202 (e.g., internal sensors). External interfaces 206 are configured to enable autonomous vehicle 100 to communicate with an external network via, for example, a wired or wireless connection, such as Wi-Fi 226 or other radios 228. In embodiments including a wireless connection, the connection may be a wireless communication signal (e.g., Wi-Fi, cellular, LTE, 5g, Bluetooth, etc.).

In some embodiments, external interfaces 206 may be configured to communicate with an external network via a wired connection, such as, for example, during testing of autonomous vehicle 100 or when downloading mission data after completion of a trip. The connection(s) may be used to download and install various lines of code in the form of digital files (e.g., HD maps), executable programs (e.g., navigation programs), and other computer-readable code that may be used by autonomous vehicle 100 to navigate or otherwise operate, either autonomously or semi-autonomously. The digital files, executable programs, and other computer readable code may be stored locally or remotely and may be routinely updated (e.g., automatically or manually) via external interfaces 206 or updated on demand. In some embodiments, autonomous vehicle 100 may deploy with all of the data it needs to complete a mission (e.g., perception, localization, and mission planning) and may not utilize a wireless connection or other connection while underway.

In the example embodiment, autonomy computing system 200 is implemented by one or more processors and memory devices of autonomous vehicle 100. Autonomy computing system 200 includes modules, which may be hardware components (e.g., processors or other circuits) or software components (e.g., computer applications or processes executable by autonomy computing system 200), configured to generate outputs, such as control signals, based on inputs received from, for example, sensors 202. These modules may include, for example, a calibration module 230, a mapping module 232, a motion estimation module 234, a perception and understanding module 236, a behaviors and planning module 238, a control module or controller 240, and a power management monitoring module 242. Power management monitor module 242, for example, may be embodied within another module, such as behaviors and planning module 238, or separately. These modules may be implemented in dedicated hardware such as, for example, an application specific integrated circuit (ASIC), field programmable gate array (FPGA), or microprocessor, or implemented as executable software modules, or firmware, written to memory and executed on one or more processors onboard autonomous vehicle 100.

Autonomy computing system 200 of autonomous vehicle 100 may be completely autonomous (fully autonomous) or semi-autonomous. In one example, autonomy computing system 200 can operate under Level 5 autonomy (e.g., full driving automation), Level 4 autonomy (e.g., high driving automation), or Level 3 autonomy (e.g., conditional driving automation). As used herein the term “autonomous” includes both fully autonomous and semi-autonomous.

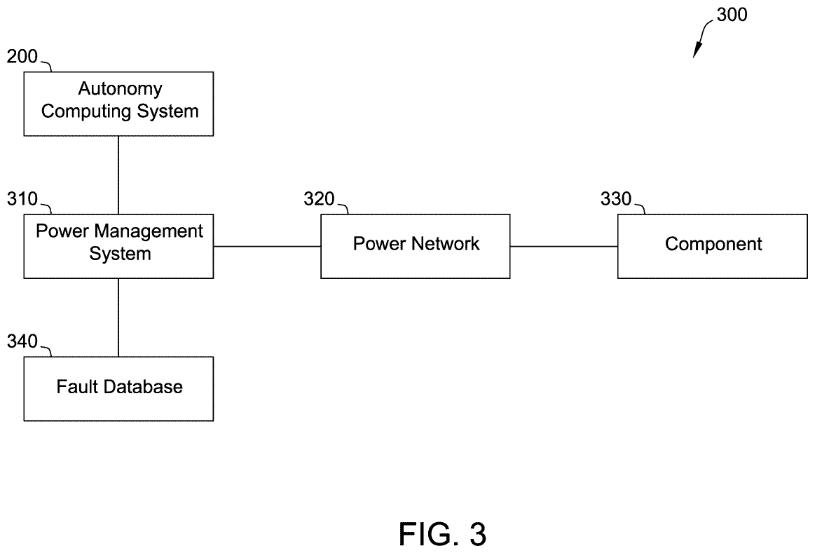

FIG. 3 is a block diagram of an embodiment of a power management system 300. Power management system 300 includes a power network computing system 310 connected by a power network 320 to a component 330. Power network computing system 310 monitors a component 330 utilized by the autonomy computing system 200 to operate an autonomous vehicle, such as autonomous vehicle 100 shown in FIGS. 1 and 2. Specifically, the autonomy computing system receives data from the power network computing system 310 relating to the status of the component 330. Accordingly, the power management system 300 allows to the autonomy computing system 200 to process inputs from the component 330 to safely operate the vehicle. The component 330 includes electric load. The electric loads include, for example, sensors and other electrical loads such as motors, processors, actuators, solenoids, sensors, lighting systems, HVAC systems, communication modules, battery management systems, power converters, navigation systems, and displays. In various embodiments, autonomy computing system 200 process the component 330 inputs to gather real-time data on the operating environment of the autonomous vehicle. Additionally, the component data is processing by the power network computing system 310 to identify a condition. The autonomy computing system 200 navigates the autonomous vehicle to a destination while adjusting and responding to the dynamic road environment using the data from the component. For example, the components 330 measure oil temperature to ensure safe operation the vehicle. Additionally, the components 330 generate environmental data to detect other vehicles on the road. The generated data from the components 330 are then transmitted to the power network computing system 310 for processing.

In various embodiments, the power management system 300 monitors the component 330 for a condition impacting operation of the component 330. The power management system 300 monitors the component 330 by connecting the power network computing system 310 to the component 330 through the power network 320. In various embodiments, the power network 320 includes a power supply and one or more cables connecting the power network 320 to the component 330. The power supply provides power, e.g., direct current, through the power network 320 to the component 330. The power network 320 also supplies power, e.g., direct current, to the power network computing system 310. The electrical properties of the power network 320 include, for example, conductivity, resistivity, permittivity, permeability, capacitance, inductance, resistance, impedance, and loss functions of the power network 320. In certain embodiments the power management system 300 is connected to autonomy computing system 200. For example, the power management system 300 transmits indications associated with the condition from the power network computing system 310 to the autonomy computing system 200.

In various embodiments, the power management system 300 is controlled by power management monitoring module 242 of the autonomy computing system 200. In some embodiments, the power network computing system 310 is integrated into the power management system 300. In some embodiments, the power network computing system 310 initiates the power management system 300 to generate, transmit, receive, and process a test signal that is used to the detect a condition impacting component 330. In some embodiments, the power management system 300 is a standalone module that connects to the component 330 and the power network computing system 310.

The power network computing system 310 includes a processor and a memory configured to generate, transmit, receive, and process the test signals for detecting the condition. In various embodiments, the power network computing system 310 includes a first connection to the power network computing system 310 and a second connection to the component 330. The first connection includes a data connection between the power management system 300 and the power network computing system 310. The second connection includes the connection between the power management system 300 and the component 330. In various embodiments, the component monitoring module connects to the component and the autonomy computing system. The power management system 300 generates a known test signal to be transmitted through power network 320 to evaluate the status of component 330.

In various embodiments, the power management system 300 can modify the test signal to best interrogate the power network 320 to detect the condition. For example, the test signal amplitude, phase, frequency, waveform, Signal-to-Noise Ratio (SNR), propagation speed, power, voltage, and current are determined based on the properties of the power network 320. In various embodiments, the test signal can be a standardized test signal for the power network 320. For example, a power network 320 is monitored for a condition utilizing one configuration of the test signal. In some embodiments, the power management system 300 generates a specialized test signal for each component 330.

Upon generation of the test signal parameters, the power management system 300 transmits the test signal through the power network 320. The transmission of the test signal through the power network 320 alters the test due to the physical characteristics of the power network 320 as an imperfect electrical conductor. The transmission of the test signal includes transmitting the generated test signal along a signal path through the power network 320 and component 330. In various embodiments, the condition affecting the component alters the connection between the power network and the component. The power management system 300 receives a test signal response from the power network 320 upon transmission of the test signal through the power network 320. The physical characteristics of the power network 320 and the component 330 alter the test signal as it is transmitted through power network 320. The test signal response reflects the alteration of the test signal caused by transmission through the power network 320. In various embodiments, when the component 330 experiences a condition, the characteristics of the test signal response will change.

The physical characteristics of the power network 320 are determined by measuring electrical properties of the power network 320. Correlating electrical properties of the power network 320 to the condition provides a non-destructive technique for monitoring the power network 320. In various embodiments the physical characteristics of the power network 320 can be analyzed by measuring electrical properties of the power network 320, including, for example, conductivity, resistivity, permittivity, permeability, capacitance, inductance, resistance, impedance, and loss functions of the power network 320.

The power management system 300 processes the test signal response to detect a condition using the power network computing system 310. Processing the test signal response includes, for example, computing a change between the test signal and the test signal response. The change is then analyzed by the power network computing system 310 to associate the test signal response to the condition affecting the power network or the component. In various embodiments, the power network computing system 310 associates the condition with the component 330.

The power management system 300 processes test signal response to detect a condition by analyzing the test signal response using the power network computing system 310. For example, to analyze the test signal response, the power network computing system 310 compares the transmitted test signal to the received test signal response. In some embodiments, discrepancies between the test signal and the test signal response are analyzed by the power network computing system 310 to detect the condition.

Upon detection of the condition, by the system, the power network computing system 310 compares the condition to a fault database 340. The fault database 340 is stored on a memory device. The memory device may be associated with the power management system 300. In some embodiments, the fault database 340 may be stored on a memory device of the power network computing system 310. The fault database 340 includes data corresponding to a plurality of known conditions.

The power management system 300 compares data associated with the power network 320, the component 330, and the test signal response analyzed by the power network computing system 310 to identify the condition using the fault database 340. For example, the power management system 300 compares the test signal data to the fault database 340 to identify the condition. The known conditions in the fault database are associated with instructions executable by the power network computing system 310 to respond to the identified condition. In various embodiments, the instructions are stored on the fault database 340. In various embodiments, the instructions may be transmitted from the fault database 340 to the power network computing system 310 upon detection of the condition on the fault database 340.

In some embodiments, the power management system 300 performs additional processing to identify the condition directly from the test signal response. For example, the power management system 300 processes the test signal data and identifies a condition where an impedance measurement indicates a component failure. The power management system 300 can directly associate the impedance measurement to a condition. In various embodiments, the power management system 300 transmits an indication to the power network computing system 310 corresponding to the detected condition.

In some embodiments, when the condition does not correspond to a known condition on the fault database, the power management system 300 performs additional diagnostics to determine the response to the condition and logs the condition to the fault database 340 for future processing. For example, when the condition does not correspond to a known condition in the fault database 340, the power management system 300 computes a severity assessment. The severity assessment is computed by the power network computing system 310 to evaluate and classify the impact of the condition on the autonomous operation of the vehicle. For example, the power management system 300 processes data corresponding to the condition to determine a severity. The severity level is computed by a processor on the power network computing system 310 by evaluating factors of the condition such as the likelihood of a component 330 failure, consequences of a component 330 failure, or the ability of the power network computing system 310 to mitigate and manage the condition autonomously.

For example, the power network computing system 310 identifies the condition affecting the component 330 as a minor condition. The minor condition causes degradation to the performance of the component 330, but the condition does not significantly affect the functionality of the autonomous vehicle. For a minor condition, the power network computing system 310 initiates conditional operation of the component 330. Additionally, the power network computing system 310 can identify a catastrophic fault from the severity assessment. The catastrophic fault includes major component 330 malfunctions that pose an immediate and serious risk to safety. The power network computing system 310 initiates the autonomy computing system 200 to perform a minimum risk maneuver (MRM) upon identifying the condition as a catastrophic fault from the severity assessment. The MRM is a pre-defined autonomous vehicle operation to safely halt the autonomous vehicle. In various embodiments, the severity assessment determines the condition affecting the component 330 is an intermediate fault. The intermediate fault includes conditions that do not pose an immediate danger but impact the operation of the component 330. When the power network computing system 310 determines the condition is an intermediate fault from the severity assessment, the power network computing system 310 initiates reduced or conditional operation of the component 330.

In some embodiments, the power network computing system 310 processes the test signal response using a machine learning module. The machine learning module is trained on data from the fault database 340 to detect the condition from the test signal response. Accordingly, the test signal response captures the effect of the physical condition of the power network 320 and the component 330 as it is transmitted from the power management system 300 to the component 330 and returns to the power management system 300.

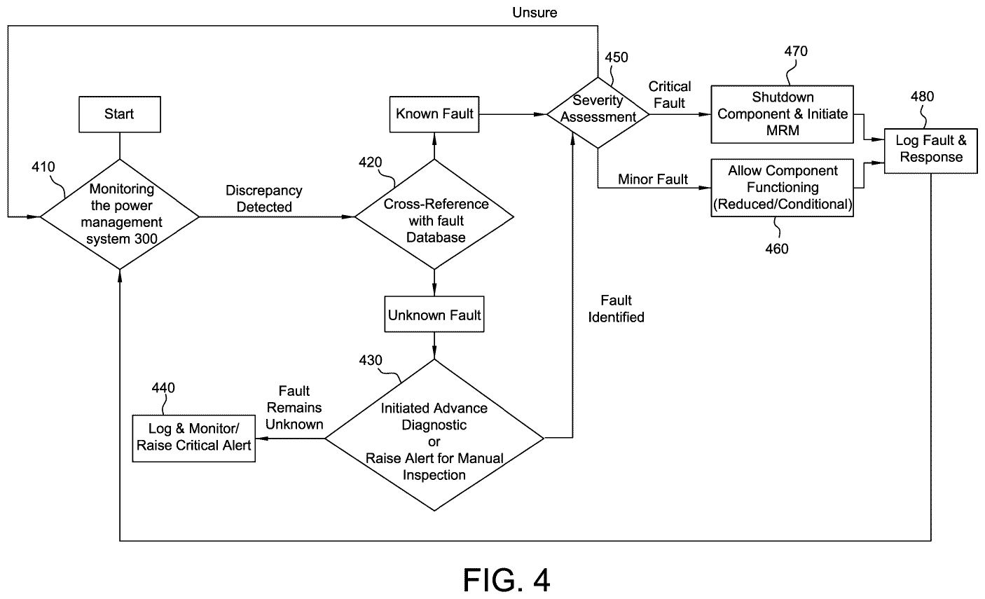

FIG. 4 is a flow chart of an embodiment of a method of operation of the power management system 300 shown in FIG. 3. In various embodiments, the component 330 is monitored 410 by power management system 300. In various embodiments, the power management system 300 is connected to the power management system. The power management system 300 includes the using the power network computing system to monitor the power network. The power network computing system includes a processor for monitoring the power network. For example, the processor is configured to utilize techniques including channel sounding or reflectometry to identify a condition on the power network. The power network computing system is configured to detect a condition affecting a component by processing a test signal response from a test signal transmitted through the power network. In some embodiments, the test signal includes a is generated by a signal generator for transmission through the power network. Accordingly, the processor thereby identifies a condition on the power network by processing the test signal response. Processing the test signal response incudes comparing the generated test signal to the test signal response. In various embodiments, the test signal response is then compared 420 against a fault database. Upon comparing 420 the condition to the fault database, the power management system 300 determines whether the received test is a known fault or an unknown fault.

When the condition detected by the power management system 300 does not correlate to a known fault on the fault database, the autonomy computing system initiates 430 additional diagnostics. In various embodiments, the additional diagnostics include collecting additional data. The additional data may be received from additional components connected to the power management system 300. In some embodiments, the power network computing system 310 processes data from the autonomy computing system 200 to analyze the unknown condition. For example, the power network computing system records the time at which the condition occurred, the effect of the condition on additional components, or the impact of the condition on the component from the autonomy computing system 200.

In various embodiments, the power management system 300 processes the data from the power network computing system to further analyze the unknown condition. The power network computing system transmits additional diagnostic data is transmitted to the power management system 300. The power management system 300 analyzes the condition again using the additional diagnostic data from the power network computing system 310.

When the power management system 300 cannot correlate the condition to a known fault, the power network computing system records and monitors 440 the condition. Detection of an unknown fault from the condition may also result in the power network computing system transmitting and alert to an operating hub to indicate the status of the autonomous vehicle. Additionally, or alternatively, when the additional diagnostic data enables the correlation of the condition to a known fault, the power management system 300 computes 450 a severity assessment.

In various embodiments, the power network computing system computes 450 the severity assessment when the condition has been correlated to a known fault. The severity assessment processes data associated with the detected condition and data from the fault database based on the correlation of the condition to the known fault by the power network computing system. The power network computing system determines whether the condition is a minor fault or a critical fault from the severity assessment. When the power network computing system determines the condition is a minor fault, the autonomy computing system 200 initiates 460 conditional operation of the component. For example, initiating 460 conditional operation includes the autonomy computing system reducing the operational capacity of the component or limiting operation of the component to specific circumstances based on a received indication from the power network computing system. When the power network computing system determines that the condition is a critical fault, the autonomy computing system may initiate 470 shut down of the component or initiate a minimum risk maneuver. Additionally, when the power network computing system performs a severity assessment on the condition, the autonomy computing system 200 will log 480 the condition and the response by the autonomy computing system 200 to the condition. In some embodiments, the power network computing system transmits the log of the condition and the response to an operating hub to indicate a status of the autonomous vehicle affected by the condition. Additionally, or alternatively when the severity assessment 450 does not meet a confidence threshold for the severity assessment, the autonomy computing system may continue monitoring the condition.

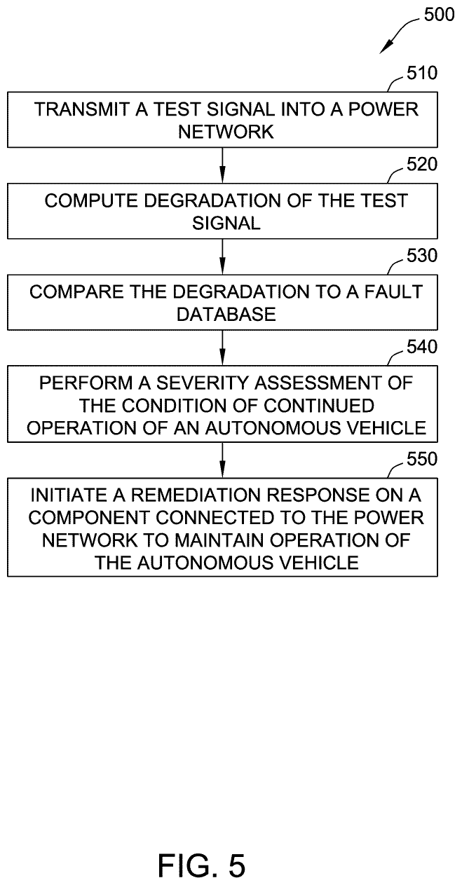

FIG. 5 is a flow diagram of one embodiment of a method 500 of detecting power network faults, such as power network 320 shown in FIG. 3. In certain embodiments, method 500 may be perform on an autonomous truck, such as autonomous truck 100 shown in FIGS. 1 and 2. Method 500 begins by transmitting 510 a test signal into a power network. The test signal includes a frequency modulated signal generated by a frequency modulated signal generator configured to generate a frequency modulated test signal. The test signal is processed by the to analyze physical characteristics of the power network. As the test signal is transmitted through the power network the physical characteristics of the power network and the component degrade the test signal as it is transmitted through the power network. In various embodiments, the degradation corresponds to a condition. Accordingly, the status of the power network and the status of the component are measurable through the degradation. For example, a condition on the power network results in a first type of degradation and a condition on the component causes a second type of degradation. Accordingly, as the power management system receives the test signal response that has been transmitted through the power network, the power management system can correlate physical characteristics of the power network and the component to a condition.

The method may then proceed to computing 520 the degradation of the test signal. In various embodiments, the power management system is configured to perform operations including channel sounding or reflectometry to interpret the test signal response from the power network. The power management system processes the transmitted test signal to identify a condition on the power network. In some embodiments, the condition on the power network corresponds to a condition affecting a component. When the power management system has detected a condition by interpreting the degradation of the test signal in step 520 the power management system compares 530 the condition to a fault database. For example, the power management system compares the computed degradation to the fault database. The method 500 further includes performing 540 a severity assessment. In various embodiments the severity assessment is performed when the detected condition is insufficient to correlate the condition to a known fault on the fault database. To perform the severity assessment, the power management system collects additional data associated with the condition to determine the severity of the condition. The severity of the condition determines the remediation response. Using the severity assessment, the power management system initiates 550 the remediation response to maintain 550 operation of the autonomous vehicle. For example, the power management system initiates reduced operating capacity for the component or implements conditional operation of the component. In some embodiments, the power management system initiates shutdown of the component.

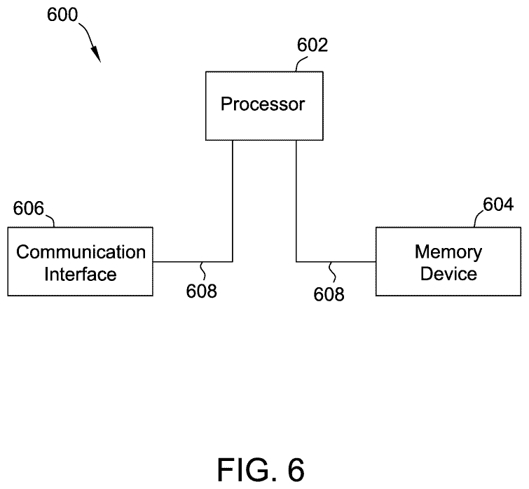

FIG. 6 is a block diagram of an example computing device 600. Computing device 600 includes a processor 602 and a memory device 604. The processor 602 is coupled to the memory device 604 via a system bus 608. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are example only, and thus are not intended to limit in any way the definition or meaning of the term “processor.”

In the example embodiment, the memory device 604 includes one or more devices that enable information, such as executable instructions or other data (e.g., sensor data), to be stored and retrieved. Moreover, the memory device 604 includes one or more computer readable media, such as, without limitation, dynamic random access memory (DRAM), static random access memory (SRAM), a solid state disk, or a hard disk. In the example embodiment, the memory device 604 stores, without limitation, application source code, application object code, configuration data, additional input events, application states, assertion statements, validation results, or any other type of data. The computing device 600, in the example embodiment, may also include a communication interface 606 that is coupled to the processor 602 via system bus 608. Moreover, the communication interface 606 is communicatively coupled to data acquisition devices.

In the example embodiment, processor 602 may be programmed by encoding an operation using one or more executable instructions and providing the executable instructions in the memory device 604. In the example embodiment, the processor 602 is programmed to select a plurality of measurements that are received from data acquisition devices.

In operation, a computer executes computer-executable instructions embodied in one or more computer-executable components stored on one or more computer-readable media to implement aspects of the disclosure described or illustrated herein. The order of execution or performance of the operations in embodiments of the disclosure illustrated and described herein is not essential, unless otherwise specified. That is, the operations may be performed in any order, unless otherwise specified, and embodiments of the disclosure may include additional or fewer operations than those disclosed herein. For example, it is contemplated that executing or performing a particular operation before, contemporaneously with, or after another operation is within the scope of aspects of the disclosure.

An example technical effect of the methods, systems, and apparatus described herein includes at least one of: improved sensor error detection, increased autonomy computing system reliability, and component level condition analysis and logging.

Some embodiments involve the use of one or more electronic processing or computing devices. As used herein, the terms “processor” and “computer” and related terms, e.g., “processing device,” and “computing device” are not limited to just those integrated circuits referred to in the art as a computer, but broadly refers to a processor, a processing device or system, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory includes non-transitory computer-readable media, which may include, but is not limited to, media such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

What is claimed is:

1. A power management system for detecting a fault in a power network, the power management system comprising:
a signal generator configured to transmit a test signal through the power network to a component;
a receiver coupled to the power network and configured to receive a test signal response corresponding to the test signal;
a memory storing a fault database; and
a processor coupled to the receiver and the memory, the processor configured to process the test signal response to detect a condition in the power network;
compare the condition to a fault database; and
initiate shutdown of the component or conditional operation of the component based on a severity assessment from the fault database.

2. The system of claim 1, wherein the test signal does not degrade the power network or the component.

3. The system of claim 1, wherein the power network supplies direct current power from a direct current power supply to the component.

4. The system of claim 1, wherein the signal generator includes a frequency modulated signal generator configured to generate a frequency modulated test signal.

5. The system of claim 1, wherein the condition is at least one of a software bug, a hardware failure, or a power supply fluctuation.

6. The system of claim 1, wherein the processor is further configured to execute a machine learning module to process the test signal.

7. The system of claim 1, wherein the fault database associates the condition with a physical characteristic of the power network.

8. A power management system, the system comprising:
an electric load of an autonomy computing system; and
a power network electrically connected to the electric load, wherein the power network is monitored by a processor, the processor configured to:
identify a condition on the power network from a test signal transmitted through the power network;
identify a fault corresponding to the condition in a fault database;
compute a severity assessment for the fault; and
initiate a remediation response comprising shutdown of the electric load or reduced operation of the power network.

9. The system of claim 8, wherein the test signal does not degrade the power network or the electric load.

10. The system of claim 8, wherein the power network supplies direct current power from a direct current power supply to the electric load.

11. The system of claim 8, further comprising generating the test signal with a frequency modulated signal generator configured to generate a frequency modulated test signal.

12. The system of claim 8, wherein the condition is at least one of a software bug, a hardware failure, or a power supply fluctuation.

13. The system of claim 8, further comprising executing a machine learning module to process the test signal.

14. The system of claim 8, wherein the fault database associates the condition with a physical characteristic of the power network.

15. A method for detecting power network faults, the method comprising:
transmitting a test signal into a power network;
computing degradation of the test signal;
detecting a condition on the power network based on the degradation, the detection comprising:
comparing the degradation to a fault database; and
performing a severity assessment of the condition on continued operation of an autonomous vehicle; and
initiating a remediation response on a component connected to the power network to maintain operation of the autonomous vehicle.

16. The method of claim 15, wherein the initiation of the remediation response comprises initiating a shutdown of the component or conditionally operating the component.

17. The method of claim 15, further comprising generating a known test signal based on electrical properties of the power network connection.

18. The method of claim 15, further comprising generating the test signal with a frequency modulated signal generator configured to generate a frequency modulated test signal.

19. The system of claim 1, further comprising executing a machine learning module to process the test signal.

20. The method of claim 15, further comprising associating the condition to a physical characteristic of the power network.
